(19) United States
(12) Patent Application Publication
(10) Pub. No.: US 2026/0081566 A1
(43) Pub. Date: Mar. 19, 2026

(54) BOOST DROOP CATCHER

(71) Applicant: SKYWORKS SOLUTIONS, INC., Irvine, CA (US)

(72) Inventor: Wendy Ng, Los Gatos, CA (US)

(21) Appl. No.: 19/289,544

(22) Filed: Aug. 4, 2025

Related U.S. Application Data
(60) Provisional application No. 63/681,300, filed on Aug. 9, 2024.

(51) Int. Cl. H03F 1/30; H03K 3/037

(52) U.S. Cl. CPC H03F 1/305; H03K 3/0377; H03F 2200/471

(57) ABSTRACT

A system for controlling a duty cycle of a boost loop is presented. The system includes an amplifier having a first input, a second input, and an output; a current source configured to source and sink current at the output of the amplifier; a duty cycle controller coupled to the output of the amplifier and configured to control the duty cycle of the boost loop by increasing the duty cycle when an output voltage of the boost loop falls below a first threshold voltage, and decreasing the duty cycle when the output voltage of the boot loop rises above a second threshold voltage; and an impedance coupled to a power source and configured to store energy based on the duty cycle of the boost loop.

### CROSS-REFERENCE TO RELATED APPLICATIONS

This application claims priority under 35 U.S.C. § 119 (e) to U.S. Provisional Patent Application 63/681,300, titled BOOST DROOP CATCHER, filed on Aug. 9, 2024, which is hereby incorporated by reference in its entirety for all purposes.

### BACKGROUND

### 1. Field of the Disclosure

At least one example in accordance with the present disclosure relates generally to controlling output voltages during transitions in load levels.

### 2. Discussion of Related Art

During operation of various circuits, changes in the load level (or load utilization) can result in a decrease or increase of a voltage being provided by a power source or similar device to said load.

### SUMMARY

According to at least one aspect of the present disclosure a system for controlling a duty cycle of a boost loop is presented, the system comprising: an amplifier having a first input, a second input, and an output; a current source configured to source and sink current at the output of the amplifier; a duty cycle controller coupled to the output of the amplifier and configured to control the duty cycle of the boost loop by increasing the duty cycle when an output voltage of the boost loop falls below a first threshold voltage, and decreasing the duty cycle when the output voltage of the boot loop rises above a second threshold voltage; and an impedance coupled to a power source and configured to store energy based on the duty cycle of the boost loop.

In some examples, the system further comprises a switchable diode coupled to the impedance and to a load connection of the boost loop; a switching device coupled to the impedance and the switchable diode at a first connection and to a reference node at a second connection, the duty cycle controller being configured to control a state of the switching device based on the duty cycle of the boost loop. In some examples, the first input of the amplifier is coupled to a digital-to-analog converter and the second input of the amplifier is coupled to a voltage divider, the voltage divider being coupled between the load connection and a reference node. In some examples, an output signal of the amplifier is based on a feedback signal provided by the voltage divider and a bias signal provided by the digital-to-analog converter. In some examples, the bias signal is based on an output of a load coupled to the boost loop. In some examples, the current source is configured to source or sink the current at the output of the amplifier responsive to a voltage droop occurring at an output connection of the boost loop. In some examples, the duty cycle controller change the duty cycle of the boost loop proportionately to changes in a voltage at the output of the amplifier. In some examples, the duty cycle controller controls a switching device coupled between the impedance and ground to switch between an open state and a closed state at one or more higher frequencies based on increases in the voltage at the output of the amplifier. In some examples, the system further comprises quick-start circuitry configured to provide a first bias voltage to the first input of the amplifier, a second bias voltage to the second input of the amplifier, and a third bias voltage to the output of the amplifier during a start-up of the boost loop. In some examples, the impedance includes at least one inductor. In some examples, the duty cycle controller is coupled to a switching device and configured to control a state of the switching device based on the duty cycle of the boost loop, wherein the switching device includes: a first transistor having a source terminal coupled to the impedance, a drain terminal coupled to a reference node, and a gate terminal coupled to the duty cycle controller; and a second transistor having a source terminal coupled to the duty cycle controller, a drain terminal coupled to the reference node, and a gate terminal configured to receive the output voltage of the boost loop. In some examples, the duty cycle controller includes: a current sensing amplifier having a first input coupled to the impedance, a second input coupled to the source of the second transistor, and an output coupled to a first input of a Schmidt trigger, wherein the Schmidt trigger further has a second input coupled to an output of the amplifier, and an output coupled to an input of a driver, the driver further having an output coupled to the gate of the first transistor. In some examples, the current source is incorporated into a droop controller, the droop controller including: a first Schmidt trigger having a first input configured to receive a bias voltage, a second input configured to receive an input voltage of the system, and an output coupled to a first AND-gate and to a second AND-gate; a second Schmidt trigger having a first input configured to receive a threshold voltage, a second input configured to receive a voltage based on the output voltage of the boost loop, and an output coupled to the first AND-gate; and a third Schmidt trigger having a first input configured to receive a voltage based on the bias voltage, a second input configured to receive the voltage based on the output voltage of the boost loop, and an output coupled to the second AND-gate. In some examples, the first AND-gate includes an output coupled to a first input of a latch, the second AND-gate includes an output coupled to a second input of the latch, and the latch includes an output coupled to the current source and configured to control the current source.

According to at least one aspect of the present disclosure, a method for controlling an output voltage of a system is presented, the method comprising: monitoring the output voltage; detecting that the output voltage falls below a first threshold voltage; injecting current at the output of an amplifier responsive to detecting that the output voltage fell below the first threshold voltage; increasing the frequency of state changes between open states and closed states of a switching device situated in the boost loop and coupled to an impedance configured to store energy responsive to injecting the current; detecting that the output voltage has risen above a second threshold voltage responsive to increasing the frequency of state changes of the switching device; ceasing to inject the current responsive to detecting that the output voltage had risen above the second threshold; and decreasing the frequency of state changes between open states and closed states of the switching device responsive to ceasing to inject the current.

In some examples, decreasing the frequency of state changes of the switching device includes returning the frequency of the state changes to an original frequency prior to detecting that the output voltage fell below the first threshold voltage. In some examples, the second threshold voltage is greater than the first threshold voltage. In some examples, the second threshold voltage is approximately 99% of a target output voltage. In some examples, the system is a boost loop configured to drive a power amplifier.

According to at least one aspect of the present disclosure, at least one non-transitory computer-readable medium containing thereon instructions for controlling a duty cycle of a boost loop is presented, the instructions instructing at least one processor to: monitor the output voltage; detect that the output voltage falls below a first threshold voltage; inject current at the output of an amplifier responsive to detecting that the output voltage fell below the first threshold voltage; increase the frequency of state changes between open states and closed states of a switching device situated in the boost loop and coupled to an impedance configured to store energy responsive to injecting the current; detect that the output voltage has risen above a second threshold voltage responsive to increasing the frequency of state changes of the switching device; cease to inject the current responsive to detecting that the output voltage had risen above the second threshold; and decrease the frequency of state changes between open states and closed states of the switching device responsive to ceasing to inject the current.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a boost loop according to an example;

FIG. 2 illustrates duty cycle controller according to an example; and

FIG. 3 illustrates droop controller according to an example.

### DETAILED DESCRIPTION

For some amplifier systems, such as power amplifier systems, the output load may rapidly change from a light load level to a heavy load level (that is, when the load is consuming relatively little power and changes to consuming relatively large amounts of power), the boost loop may not be able to react fast enough to raise the boost output voltage to the correct setpoint. As a result, the boost output voltage may droop (i.e., fall or remain lower than intended) for a period of time. This voltage droop may degrade performance of the amplifier system as the output voltage of the amplifier may not be as high as intended or desired until the droop ends and the boost loop voltage rises to the intended or desired level.

Examples of the present disclosure include systems and methods for preventing boost loop voltage droop as described above. In some examples, the boost output voltage may be actively monitored so that when the boost loop output voltage falls below the setpoint voltage by a threshold amount (e.g., a threshold voltage), the loop may be interrupted and current may be injected into the amplifier output (either directly, e.g., summing currents at the output of the amplifier) or indirectly, thereby pulling the amplifier output higher. Furthermore, in some examples the duty cycle of the boost regulator may be increased, enabling the boost output to reach the setpoint voltage more quickly. In some examples, when the boost loop voltage recovers to be within the threshold voltage of the setpoint voltage, current injection may cease or may be discontinued.

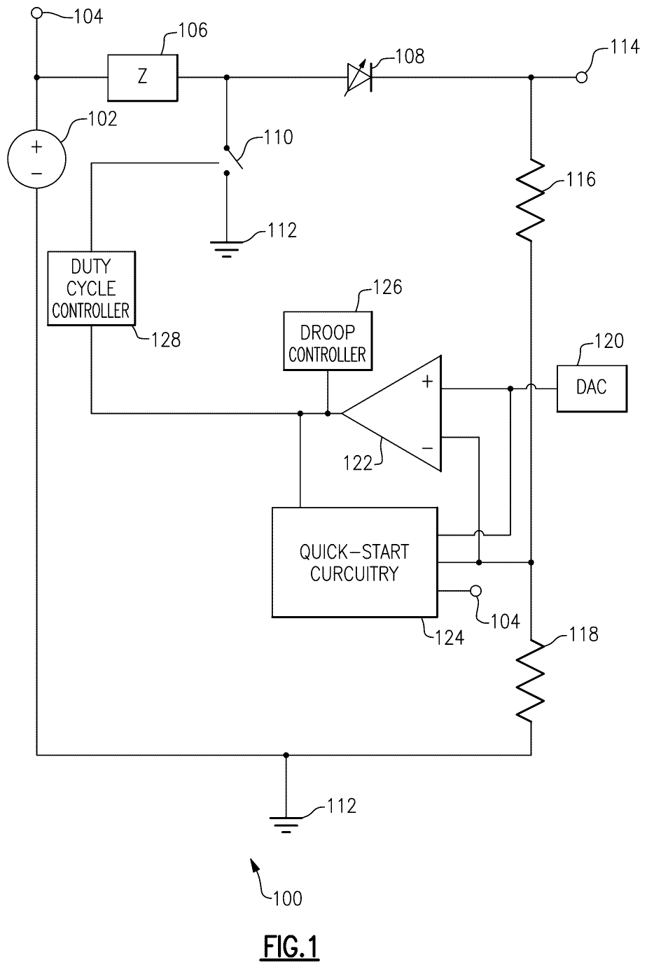

FIG. 1 illustrates a boost loop 100 according to an example. In some examples, the boost loop 100 operates by detecting when the boost output voltage falls at least a threshold voltage below the setpoint voltage. If the condition of the boost output voltage falling at least the threshold voltage below the setpoint voltage is met, the duty cycle of the boost loop is increased until the output voltage is greater than or equal to a threshold percentage of the setpoint voltage.

The boost loop 100 includes a voltage source 102, an input 104, an impedance 106, a switchable diode 108, a switching device 110, a reference node 112 (which may be the negative terminal of the voltage source 102), a first resistor 116, a second resistor 118, a digital-to-analog converter 120 (“DAC 120”), an error amplifier 122, a quick start circuit 124, a droop controller 126, and a duty cycle controller 128.

The positive terminal of the voltage source 102 is coupled to the input 104 and the impedance 106, and is configured to provide an input voltage to the input 104 and the impedance 106. The negative terminal of the voltage source 102 is coupled to the second resistor 118. The input 104 is coupled to the quick start circuit 124. The impedance 106 is coupled to the switch 110 and to an anode of the switchable diode 108. The switching device 110 is coupled to the reference node 112 and to the duty cycle controller 128. A cathode of the switchable diode 108 is coupled to the output 114 and to the first resistor 116. The first resistor 116 is coupled to the second resistor 118, the quick start circuit 124, and the inverting input of the error amplifier 122. The DAC 120 is coupled to the non-inverting input of the error amplifier 122 and to the quick start circuit 124. The quick start circuit 124 is also coupled to the output of the error amplifier 122. The output of the error amplifier 122 is coupled to the duty cycle controller 128. The droop controller 126 is coupled to the duty cycle controller 128. The duty cycle controller 128 is coupled to the switching device 110 and is configured to control the state of the switching device 110.

In general terms, the boost loop 100 works as follows: the switching device 110 has two states, an open state (e.g., non-conducting or “off” state), and a closed state (e.g., conducting or “on” state). When the switching device 110 is closed, there is a loop from the positive output of the voltage source 102 through the impedance 106, through the switching device 110, and back to the negative terminal of the voltage source 102. When in this state, the impedance 106 (which may, in some examples, be one or more inductors coupled in series and/or in parallel) may accumulate energy (e.g., store energy).

By contrast, when the switching device 110 is open, the loop through the switching device 110 to the reference node 112 becomes and/or is unavailable, and current now passes through the switchable diode 108 to the output 114, as well as through the resistors 116, 118 to the reference node 112 and to the quick start circuitry 124 and the inverting input of the error amplifier 122. If the impedance 106 contained any stored energy, some of that stored energy is discharged (e.g., as current) through the switchable diode 108, thereby raising the boost output voltage at the output 114 and at the node between the first resistor 116 and second resistor 118 (e.g., at the inverting input of the error amplifier 122).

As described above, the boost loop 100 can raise the voltage at the output 114 and elsewhere in the circuit by selectively opening and closing the switching device 110. However, as discussed above, when the load level (e.g., the power drawn at the output 114) increases, the boost loop 100 may not be able to raise the output voltage to the setpoint level. To raise the boost output voltage to the setpoint level, the duty cycle of the boost loop 100 may be changed.

In the example of FIG. 1, the duty cycle of the boost loop 100 is controlled by the duty cycle controller 128. The duty cycle controller 128 receives a first input signal from the error amplifier 122 and compares that first input signal to a current sensed at the terminal of the switching device 110 coupled to the impedance 106 and the switchable diode 108. The sensed current may be converted to a voltage, given a resistance; thus, the sensed current may instead be a sensed voltage. If the difference between the output of the error amplifier and the sensed current or voltage exceeds the threshold voltage, the duty cycle controller 128 may increase the duty cycle of the boost loop 100 by increasing the frequency of opening and closing the switching device 110. The boost output voltage (e.g., the voltage at the output 114) may increase as the duty cycle of the boost loop 100 increases.

The output of the error amplifier 122 is determined by comparing a reference voltage provided by the DAC 120 to an amplifier input voltage provided to the inverting input of the error amplifier 122, and then outputting a voltage based on the difference between the reference voltage and the amplifier input voltage. The signal provided by the DAC 120 may be based on an output signal from the load (not shown).

The droop controller 126 is configured to inject current into the same node to which the error amplifier 122 provides its output. This current may be used to increase the duty cycle of the boost loop 100 because the duty cycle controller 128 may be configured to increase the duty cycle proportionately to the value of the voltage at the node corresponding to the output of the error amplifier 122.

The quick start circuit 124 may be configured to assert or force a voltage or current at the inputs and output of the error amplifier 122 to assist the error amplifier 122 in operation. In some examples, the quick start circuit 124 may assert such a voltage or current during a start up time of the boost loop 100.

In some examples, the switchable diode 108 may be implemented using at least one transistor configured to selectively operate in either a transistor or a diode mode. In some examples the switchable diode 108 may be a standard diode that is not configured to switch.

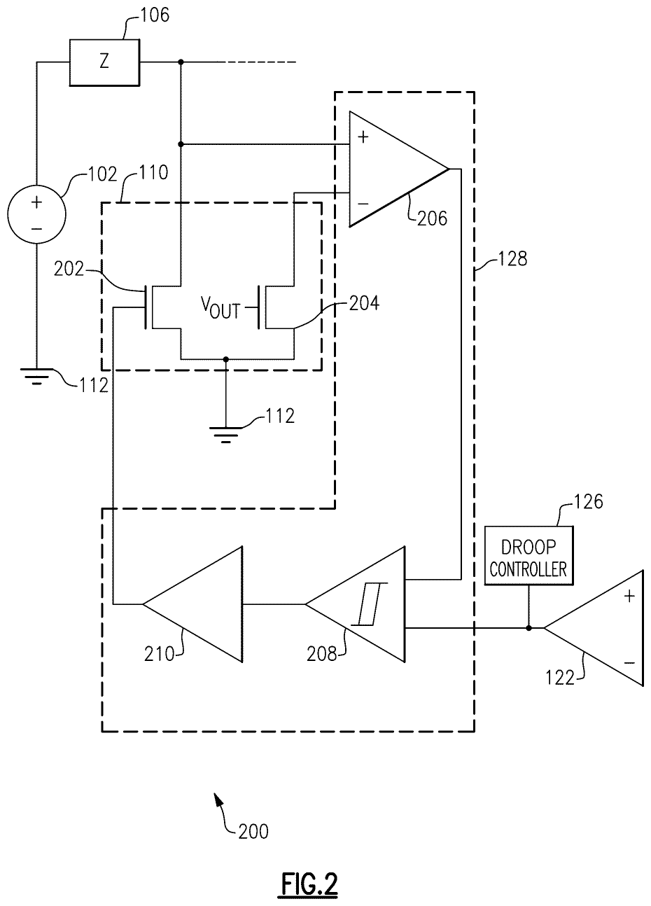

FIG. 2 illustrates a more detailed view of the duty cycle controller 128 and the switching device 110 in context according to an example. The switching device 110 includes a first transistor 202 and a second transistor 204. The duty cycle controller 128 includes a Schmitt trigger 208 (or similar device), a driver 210, and a current sensing amplifier 206.

The non-inverting input of the current sensing amplifier 206 is coupled to the impedance 106 and to a first drain or source terminal of the first transistor 202. The inverting input of the current sensing amplifier 206 is coupled to a first drain or source terminal of the second transistor 204. The first drain or source terminal of the first transistor 202 is further coupled to the impedance 106. The second drain or source terminals of both the first transistor 202 and the second transistor 204 are coupled to the reference node 112. The gate of the second transistor 204 is configured to receive the output voltage, and the gate of the first transistor 202 is coupled to the output of the driver 210.

The output of the current sensing amplifier 206 is coupled to a first input of the Schmitt trigger 208. The output of the error amplifier 122 and the droop controller 126 are coupled a second input of the Schmitt trigger 208. The output of the Schmitt trigger 208 is coupled to an input of the driver 210 (the driver 210 may be a buffer or similar device configured to buffer the output of the Schmitt trigger 208).

As mentioned above, the duty cycle of the boost loop 100 may be increased when the boost output voltage falls below a threshold voltage or level (e.g., percentage) of the setpoint voltage. The topology depicted in FIG. 2 is one way in which the duty cycle of the boost loop 100 may be increased.

The current sensing amplifier 206 may be a comparator and may output a voltage based on the difference between the voltages at its inverting and non-inverting inputs. In some examples, if the first transistor 202 and second transistor 204 are both closed, both inputs are pulled down to the reference voltage and the current sensing amplifier 206 may have no output or a small output. If both the first transistor 202 and the second transistor 204 are open, a similar situation may occur except that both inputs of the current sensing amplifier 206 may be pulled up to the voltage of the node connected between the impedance 106 and the first input of the current sensing amplifier 206. However, when only one transistor is open and the other is closed, of the first transistor 202 and second transistor 204, the voltages at the inputs to the current sensing amplifier 206 may be different, and thus the current sensing amplifier 206 may provide an output to a first input of the Schmitt trigger 208.

The Schmitt trigger 208 may output a signal provided the inputs change enough to trigger a change in the output of the Schmitt trigger 208. That is, the Schmitt trigger 208 may output a signal that only changes when the input voltage rises or falls below a given level. The output of the error amplifier 122 and the output of the droop controller 126 may be provided to a second input of the Schmitt trigger 208, and the voltages provided to the first input and second input of the Schmitt trigger 208 may determine the bias voltage (e.g., the voltage at which the Schmitt trigger 208 output switches polarity). As a result, the current injected by the droop controller 126 may be used to control the output of the Schmitt trigger 208 by either changing the bias voltage or changing the input voltage.

The driver 210 may buffer the output of the Schmitt trigger 208 and provide a signal to the gate of the first transistor 202, thereby controlling the state of the first transistor 202. The output voltage provided to the second transistor 204 may depend, in part, on the boost output voltage of the boost loop 100 as well. Thus, the output of the current sensing amplifier 206 may depend on both the output voltage and the output of the driver 210.

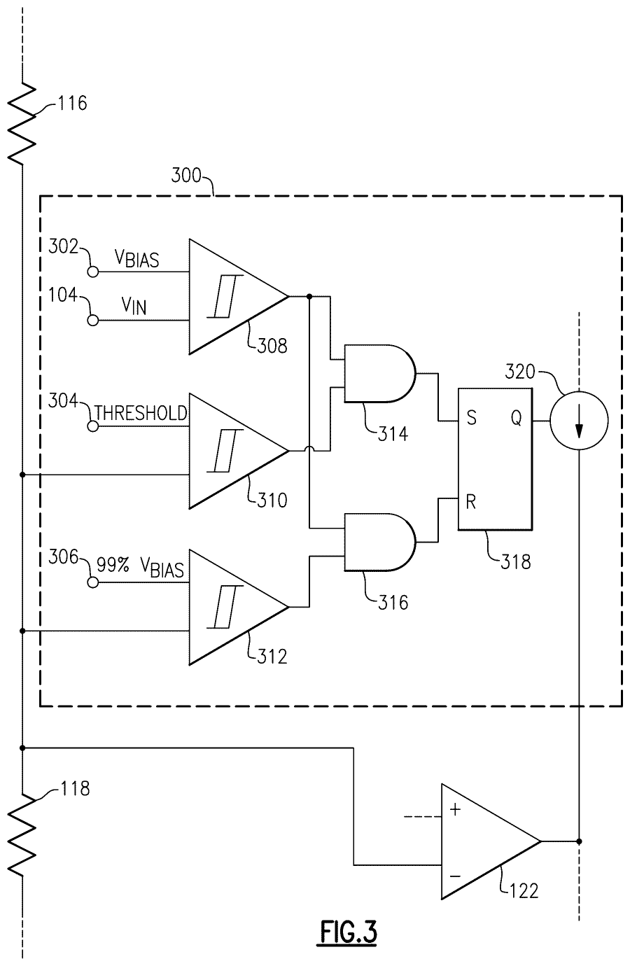

FIG. 3 illustrates a droop controller 300 according to an example. The droop controller 300 may be one example of an implementation of the droop controller 126 of FIGS. 1 and 2.

The droop controller 300 includes a bias node 302, a threshold node 304, a target node 306, a first Schmitt trigger 308, a second Schmitt trigger 310, a third Schmitt trigger 312, a first AND-gate 314, a second AND-gate 316, a latch 318, and a current source 320.

A first input of the first Schmitt trigger 308 is coupled to the input node 104. The input node 104 is configured to provide the voltage at the positive terminal of the voltage source 102. A respective first input of each of the second and third Schmitt triggers 310, 312 is coupled to the node between the first resistor 116 and the second resistor 118 (the same node connected to the inverting input of the error amplifier 122). A second input of the first Schmitt trigger 308 is coupled to a bias node 302. The bias node 302 is configured to provide a bias voltage to the first

Schmitt trigger 308. A second input of the second Schmitt trigger 310 is coupled to the threshold node 304. The threshold node 304 is configured to provide a threshold voltage (e.g., the threshold node 304 provides the voltage at which the droop controller 300 is configured to turn on and at which the duty cycle of the boost loop 100 is to be increased). In some examples, the voltage provided by the threshold node 304 may be called the “threshold” voltage. A second input of the third Schmitt trigger 312 is coupled to the target node 306. The target node 306 is configured to provide a target voltage at which the boost controller 300 turns off and/or at which the duty cycle of the boost loop 100 returns to a lower value or the original value. In some examples, the target voltage provided by the target node 306 is 99% of the bias voltage, though the target voltage may be any percent of the bias voltage (e.g., 101%, 110%, 95%, 90%, and so forth).

The output of the first Schmitt trigger 308 is coupled to a first input of the first AND-gate 314 and to a first input of the second AND-gate 316. The output of the second Schmitt trigger 310 is coupled to the second input of the first AND-gate 314, and the output of the third Schmitt trigger 312 is coupled to a second input of the second AND gate 316. The output of the first

AND-gate 314 is coupled to the “set” input of the latch 318. The output of the second AND-gate 316 is coupled to the “reset” input of the latch 318. The output of the latch 318 is coupled to the current source 320 and configured to control the current source 320 using a control signal. The current source 320 has an output coupled to the same node as the output of the error amplifier 122 and may be configured to provide a current to that node (e.g., the current may be any value, for example, 1 mA, 5 uA, 10 A, and so forth).

The bias voltage (V_{bias}) may be equal to the voltage output by a DAC, such as the DAC 120 of FIG. 1. The threshold voltage (Vₜₕ) may be equal to the bias voltage times the sum of the setpoint voltage (Vₛₚ) plus or minus a constant (k), such as 0.3V. The target voltage (Vₜₐ) may be a percentage (P) of the bias voltage, for example, 99%, 90%, 10%, and so forth. In terms of equations, these voltages may be expressed as:

$${V}_{th} = {V}_{b i a s} \cdot ( {V}_{s p} - k ) \qquad ( 1 )$$

$${V}_{ta} = P \cdot {V}_{b i a s} \qquad ( 2 )$$

In other examples, the bias voltage may be the setpoint voltage, the threshold voltage may be the setpoint voltage plus or minus a constant, and the target voltage may be a percentage of the setpoint voltage.

The boost controller 300 detects when the boost output voltage is below the threshold voltage, and turns on the current source 320 to inject current so as to increase the duty cycle of the boost loop 100. The boost controller 300 detects when the boost output voltage is above the target voltage and turns off the current source 320, thereby allowing the duty cycle to return to its original and/or slower rate.

Examples of the methods and systems discussed herein are not limited in application to the details of construction and the arrangement of components set forth in the description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers, such as the duty cycle controller 128 and/or droop controller 126 and/or the quick-start circuitry 124, may execute various operations discussed above. Using data stored in associated memory and/or storage, the one or more controllers also execute one or more instructions stored on one or more non-transitory computer-readable media, which the one or more controllers may include and/or be coupled to, that may result in manipulated data. In some examples, the one or more controllers may include one or more processors or other types of controllers. In one example, the one or more controllers are or include at least one processor. In another example, the one or more controllers perform at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A system for controlling a duty cycle of a boost loop, the system comprising:
an amplifier having a first input, a second input, and an output;
a current source configured to source and sink current at the output of the amplifier;
a duty cycle controller coupled to the output of the amplifier and configured to control the duty cycle of the boost loop by increasing the duty cycle when an output voltage of the boost loop falls below a first threshold voltage, and decreasing the duty cycle when the output voltage of the boost loop rises above a second threshold voltage; and
an impedance coupled to a power source and configured to store energy based on the duty cycle of the boost loop.

2. The system of claim 1 further comprising:
a switchable diode coupled to the impedance and to a load connection of the boost loop;
a switching device coupled to the impedance and the switchable diode at a first connection and to a reference node at a second connection, the duty cycle controller being configured to control a state of the switching device based on the duty cycle of the boost loop.

3. The system of claim 2 wherein the first input of the amplifier is coupled to a digital-to-analog converter and the second input of the amplifier is coupled to a voltage divider, the voltage divider being coupled between the load connection and a reference node.

4. The system of claim 3 wherein an output signal of the amplifier is based on a feedback signal provided by the voltage divider and a bias signal provided by the digital-to-analog converter.

5. The system of claim 4 wherein the bias signal is based on an output provided to a load coupled to the load connection of the boost loop.

6. The system of claim 1 wherein the current source is configured to source or sink the current at the output of the amplifier responsive to a voltage droop occurring at an output connection of the boost loop.

7. The system of claim 6 wherein the duty cycle controller changes the duty cycle of the boost loop proportionately to changes in a voltage at the output of the amplifier.

8. The system of claim 7 wherein the duty cycle controller controls a switching device coupled between the impedance and ground to switch between an open state and a closed state at one or more higher frequencies based on increases in the voltage at the output of the amplifier.

9. The system of claim 1 further comprising quick-start circuitry configured to provide a first bias voltage to the first input of the amplifier, a second bias voltage to the second input of the amplifier, and a third bias voltage to the output of the amplifier during a start-up of the boost loop.

10. The system of claim 1 wherein the impedance includes at least one inductor.

11. The system of claim 1 wherein the duty cycle controller is coupled to a switching device and configured to control a state of the switching device based on the duty cycle of the boost loop, wherein the switching device includes:
a first transistor having a source terminal coupled to the impedance, a drain terminal coupled to a reference node, and a gate terminal coupled to the duty cycle controller; and
a second transistor having a source terminal coupled to the duty cycle controller, a drain terminal coupled to the reference node, and a gate terminal configured to receive the output voltage of the boost loop.

12. The system of claim 11 wherein the duty cycle controller includes:
a current sensing amplifier having a first input coupled to the impedance, a second input coupled to the source of the second transistor, and an output coupled to a first input of a Schmidt trigger, wherein the Schmidt trigger further has a second input coupled to an output of the amplifier, and an output coupled to an input of a driver, the driver further having an output coupled to the gate of the first transistor.

13. The system of claim 1 wherein the current source is incorporated into a droop controller, the droop controller including:
a first Schmidt trigger having a first input configured to receive a bias voltage, a second input configured to receive an input voltage of the system, and an output coupled to a first AND-gate and to a second AND-gate;
a second Schmidt trigger having a first input configured to receive a threshold voltage, a second input configured to receive a voltage based on the output voltage of the boost loop, and an output coupled to the first AND-gate; and
a third Schmidt trigger having a first input configured to receive a voltage based on the bias voltage, a second input configured to receive the voltage based on the output voltage of the boost loop, and an output coupled to the second AND-gate.

14. The system of claim 13 wherein the first AND-gate includes an output coupled to a first input of a latch, the second AND-gate includes an output coupled to a second input of the latch, and the latch includes an output coupled to the current source and configured to control the current source.

15. A method for controlling an output voltage of a system, the method comprising:
monitoring the output voltage;
detecting that the output voltage falls below a first threshold voltage;
injecting current at an output of an amplifier responsive to detecting that the output voltage fell below the first threshold voltage;
increasing a frequency of state changes between open states and closed states of a switching device situated in a boost loop and coupled to an impedance configured to store energy responsive to injecting the current;
detecting that the output voltage has risen above a second threshold voltage responsive to increasing the frequency of state changes of the switching device;
ceasing to inject the current responsive to detecting that the output voltage had risen above the second threshold; and
decreasing the frequency of state changes between open states and closed states of the switching device responsive to ceasing to inject the current.

16. The method of claim 15 wherein decreasing the frequency of state changes of the switching device includes returning the frequency of the state changes to an original frequency prior to detecting that the output voltage fell below the first threshold voltage.

17. The method of claim 15 wherein the second threshold voltage is greater than the first threshold voltage.

18. The method of claim 17 wherein the second threshold voltage is approximately 99% of a target output voltage.

19. The method of claim 15 wherein the system is a boost loop configured to drive a power amplifier.

20. At least one non-transitory computer-readable medium containing thereon instructions for controlling a duty cycle of a boost loop, the instructions instructing at least one processor to:
monitor an output voltage;
detect that the output voltage falls below a first threshold voltage;
inject current at an output of an amplifier responsive to detecting that the output voltage fell below the first threshold voltage;
increase a frequency of state changes between open states and closed states of a switching device situated in the boost loop and coupled to an impedance configured to store energy responsive to injecting the current;
detect that the output voltage has risen above a second threshold voltage responsive to increasing the frequency of state changes of the switching device;
cease to inject the current responsive to detecting that the output voltage had risen above the second threshold; and
decrease the frequency of state changes between open states and closed states of the switching device responsive to ceasing to inject the current.
